(19) United States
(12) Patent Application Publication
(10) Pub. No.: US 2015/0311132 A1
(43) Pub. Date: Oct. 29, 2015

(54) SCRIBE LINE STRUCTURE AND METHOD OF FORMING SAME

(71) Applicant: TAIWAN SEMICONDUCTOR MANUFACTURING COMPANY, LTD., Hsin-Chu (TW)

(72) Inventors: Hung-Jui Kuo, Hsin-Chu (TW); Hsien-Wei Chen, Hsin-Chu (TW)

(21) Appl. No.: 14/263,732

(22) Filed: Apr. 28, 2014

(51) Int. Cl. H01L 23/29; H01L 21/56; H01L 23/00; H01L 23/31

(52) U.S. Cl. CPC H01L 23/293; H01L 23/3135; H01L 21/56; H01L 24/02; H01L 24/05; H01L 24/13; H01L 2224/0231; H01L 2224/0237; H01L 2224/0401; H01L 2224/13023; H01L 2224/13024; H01L 2924/0635; H01L 2924/06

(57) ABSTRACT

An embodiment device includes a die, a molding compound extending along sidewalls of the die, and a first polymer layer over the die and the molding compound. The first polymer layer has a first lateral dimension. The device further includes a second polymer layer over the first polymer layer. The second polymer layer has a second lateral dimension, where the second lateral dimension is less than the first lateral dimension.

### BACKGROUND

In an aspect of conventional packaging technologies, such as fan-out packaging, polymer layers having redistribution lines (RDLs) may be formed over a die and electrically connected to active devices in a die. Input/output (I/O) pads such as solder balls on under-bump metallurgy (UBMs) may then be formed to electrically connect to the die through the RDLs. An advantageous feature of this packaging technology is the possibility of forming fan-out packages. Thus, the I/O pads on a die can be redistributed to a greater area than the die, and hence the number of I/O pads packed on the surfaces of the dies can be increased.

In typical fan-out RDL formation processes, RDLs may be formed on multiple dies simultaneously. For example, multiple dies may be placed on a carrier, and a molding compound may be dispensed between the dies. RDLs may then be formed over the dies and the molding compound. After the formation of various features, the dies may be singulated along scribe lines, which may be patterned openings in the RDLs at peripheral regions between dies.

As the number of RDLs increase in advanced packaging processes, the depth of scribe lines (e.g., patterned openings in the RDLs) may also directly increase. Deeper scribe lines may negatively affect the formation of features over RDLs (e.g., UMBs). For example, typical UBM formation may include defining a shape of the UBMs with a photoresist layer. Deep scribe lines may negatively affect the uniformity of the photoresist deposition process, which may cause defects in the subsequent UBM formation process. These defects may be especially prevalent in UBMs formed adjacent to or near a scribe line.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 12 illustrate cross-sectional views of various intermediary steps of forming a semiconductor device in accordance with some embodiments;

FIG. 13 illustrates a cross-sectional view of a semiconductor device in accordance with some alternative embodiments;

FIGS. 14 through 21 illustrate cross-sectional views of various intermediary steps of forming a device package in accordance with some embodiments; and

FIG. 22 illustrates a cross-sectional view of a device package in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include a multi-tiered step-shaped scribe line structure in redistribution (RDLs). For example, an embodiment scribe line may be a patterned opening in two, three, four, or even more consecutive RDLs. A width of the opening in a top RDL may be larger than a width of the opening in a bottom RDL. Furthermore, the top RDL may be thicker than the bottom RDL. Using this configuration, photoresists (e.g., photoresists for forming under bump metallurgies (UMBs)) may be evenly deposited in and around the scribe line opening. Thus, photoresist deposition may have improved process control (e.g., improved thickness uniformity and planarity), and various features (e.g., UBMs) may be more formed using the photoresist with increased reliability even near the scribe line.

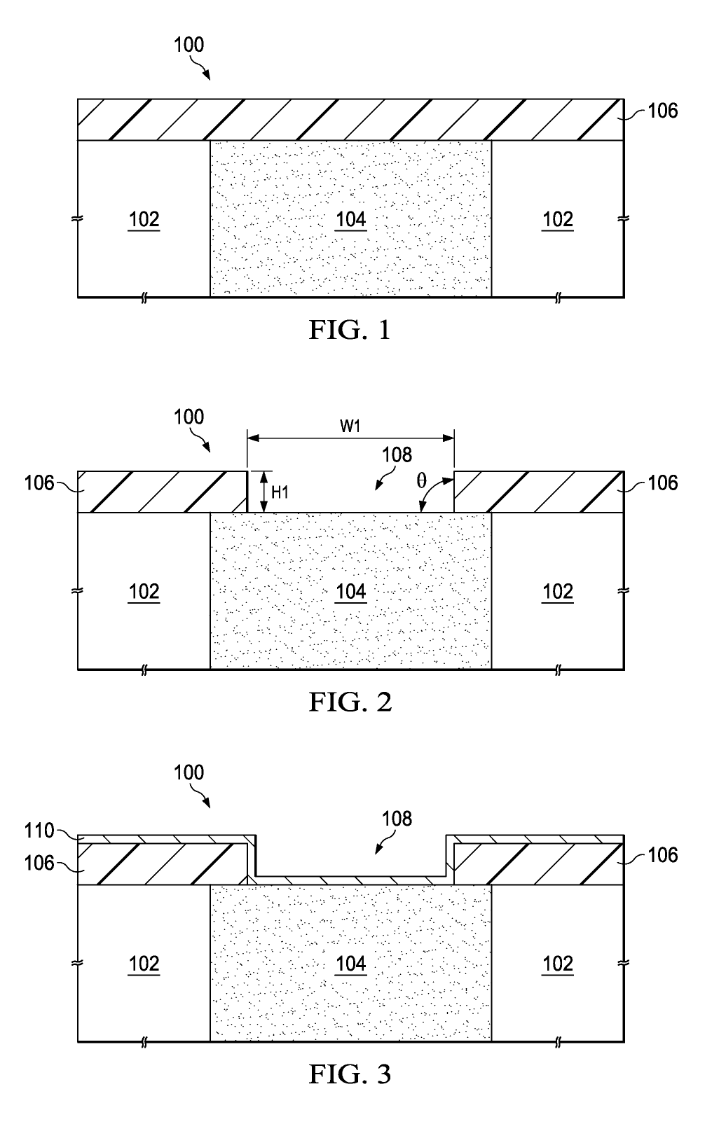

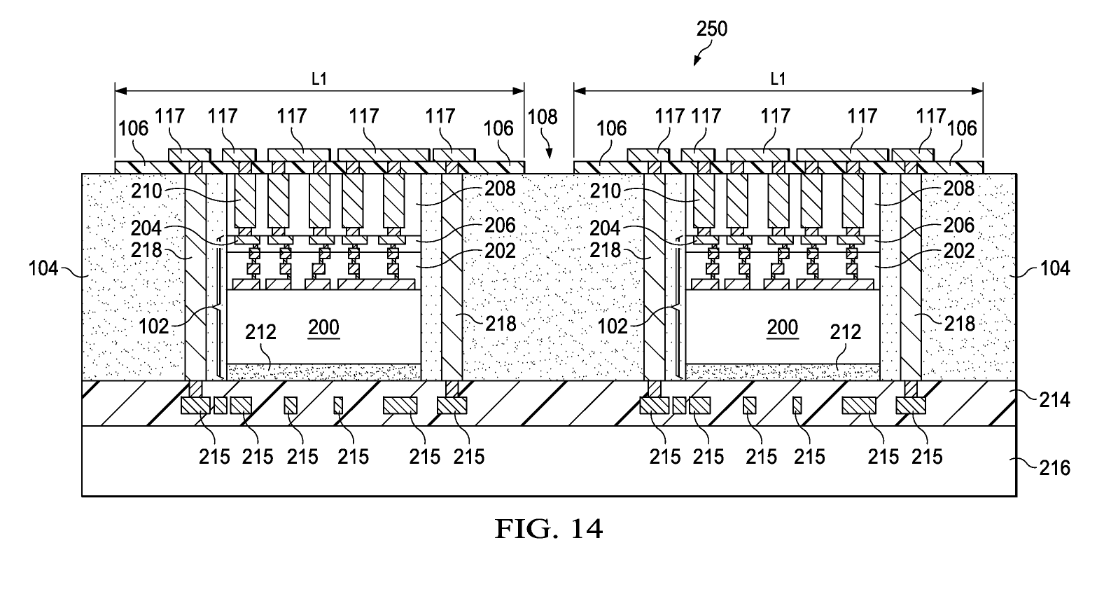

FIGS. 1 through 12 illustrate cross-sectional views of various intermediary steps of forming a semiconductor device in accordance with some embodiments. FIG. 1 illustrates cross-sectional views of portions of two dies 102. Each die 102 may be a semiconductor die and may include a substrate, active devices, and an interconnect structure (not shown). Molding compound 104 (e.g., epoxy resin, molding underfill, and the like) may be formed between dies 102. For example, dies 102 may be disposed over a carrier (not shown), and molding compound 104 may be dispensed in liquid form to fill a gap between dies 102. Subsequently, a curing process may be applied to solidify molding compound 104. The details of die 102, molding compound 104, and example additional features of a device package are discussed in greater detail with respect to FIG. 14 in subsequent paragraphs.

Polymer layer 106 is formed over dies 102 and molding compound 104. Polymer layer 106 may be formed of a photoresist material such as polybenzoxazole (PBO), an acrylic type polymer, a pheno-based polymer, and the like. Polymer layer 106 may be formed using, for example, spin-on coating techniques.

FIG. 2 illustrates the patterning of opening 108 in polymer layer 106. Opening 108 may be aligned with and mark an area between dies 102, and in subsequent process steps, opening 108 may be used as a scribe line for singulating dies 102. Thus, opening 108 is referred to as scribe line 108 hereinafter.

In some embodiments, polymer layer 106 may be patterned using a photolithography process. For example, portions of polymer layer 106 may be exposed using a photo mask (not shown). Exposed or unexposed portions of polymer layer 106 may be removed depending on whether polymer layer 106 is a positive or a negative resist. After patterning, polymer layer 106 may have a thickness H1 and a width W1 in polymer layer 106. In some embodiments, thickness H1 may be about 3 μm to about 5 μm, and width W1 may be about 60 μm to about 70 μm. Furthermore, a sidewall of scribe line 108 may have a taper angle θ relative a horizontal plane of about 50° to about 90°. In some embodiments, taper angle θ in the specified range allows for uniform and even filling (e.g., other polymer/photoresist layers) of scribe line 108 during subsequent process steps.

After patterning, a curing process may be applied to polymer layer 106 to solidify the pattern. The curing process may include increasing the temperature of patterned polymer layer 106 from room temperature (e.g., about 20° Celsius (C)) to a suitable curing temperature (e.g., between about 150° C. and about 200° C.) at a rate of 5° C. per minute. The temperature of polymer layer 106 may be maintained at the curing temperature for about two hours. After the curing process, polymer layer 106 may no longer act as a photoresist and may not be patterned using a photolithography process alone.

FIGS. 3 through 7 illustrate the formation of a conductive redistribution line (RDL) 117 (see FIG. 7) over polymer layer 106. In FIG. 3, seed layer 110 may be blanket deposited over polymer layer 106 using a sputtering or electroless plating process, for example. Seed layer 110 may comprise a conductive material such as copper, titanium, and the like. The formation of seed layer 110 may be a conformal process, and thus seed layer 110 may be disposed on a bottom surface and sidewalls of scribe line 108.

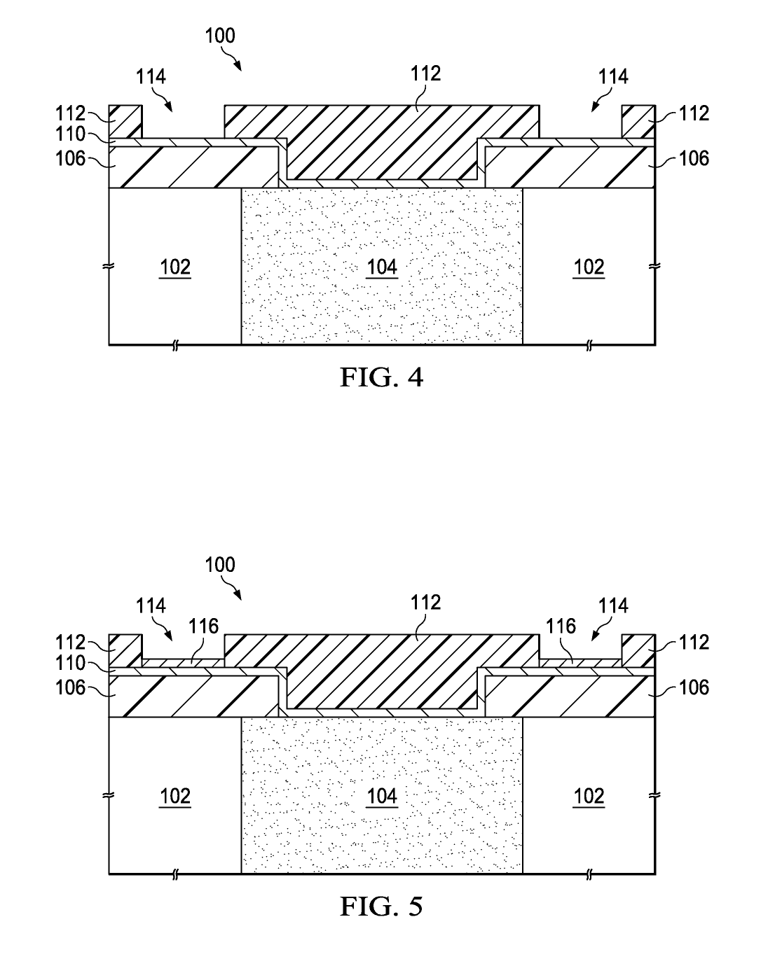

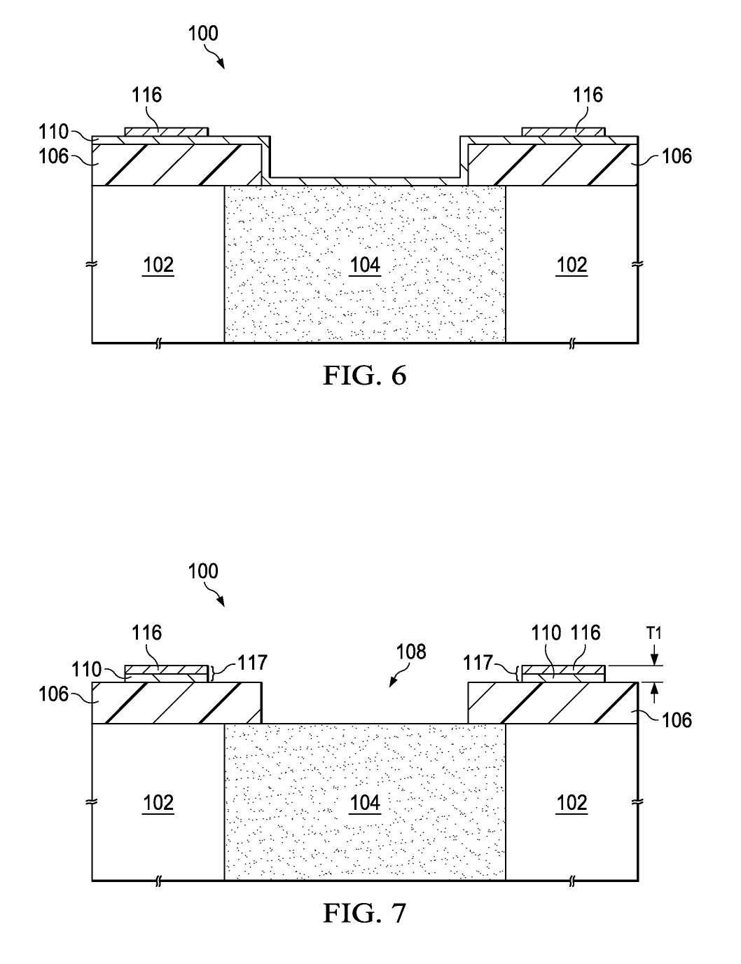

FIG. 4 illustrates a photoresist 112 may be formed over seed layer 110. Photoresist 112 may be patterned to include openings 114 for defining the shape of the RDL. Next, as illustrated by FIG. 5, a conductive material 116 (e.g., copper, titanium, and the like) may be electroless plated in openings 114. In FIG. 6, photoresist 112 is then removed, for example, using an ashing process. Finally, in FIG. 7, excess portions of seed layer 110 are removed, such as, portions not covered by conductive material 116. The removal of excess portions of seed layer 110 may be done using a combination of photolithography and etching, for example. Thus, a RDL 117 may be formed over polymer layer 106. RDL 117 may be electrically connected to dies 102, for example, by conductive vias (not shown) formed in polymer layer 106. RDL 117 may have a thickness T1, which may be about 2 μm to about 5 μm, for example.

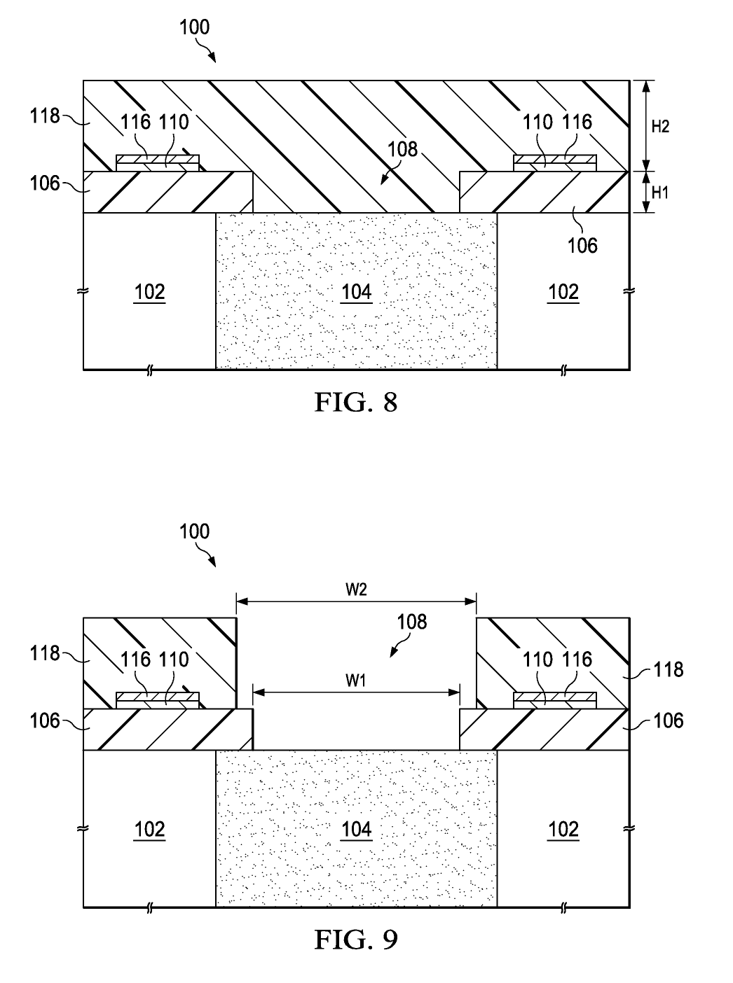

Next, referring to FIG. 8, a second polymer layer 118 may be formed over polymer layer 106 and RDL 117. Polymer layer 118 may be substantially similar to polymer layer 106. For example, polymer layer 118 may comprise a photoresist resist, which may be blanket deposited using spin-on coating techniques. Polymer layer 118 has a thickness H2, which may be greater than thickness H1 of polymer layer 106. For example, in embodiments where thickness H1 is about 3 μm to about 5 μm, thickness H2 may be about 6 μm to about 8 μm.

Polymer layer 118 may then be patterned to expose scribe line 108 in polymer layer 106 and to expand scribe line 108 into polymer layer 118. The resulting structure is illustrated in FIG. 9. Scribe line 108 in polymer layer 118 has a width W2, which may be wider than width W1 of scribe line 108 in polymer layer 106. For example, in embodiments where width W1 is about 60 μm to about 70 μm, width W2 may be about 80 μm to about 90 μm.

The patterning of polymer layer 118 may include a substantially similar process as the patterning of polymer layer 106. For example, a photolithography process may be used to pattern an opening in polymer layer 118 and to remove portions of polymer layer 118 in polymer layer 106. Because polymer layer 106 has been cured, the photolithography process may not pattern further openings in polymer layer 106. After polymer layer 118 is patterned, a curing process may be performed on polymer layer 118. The curing process may change the chemical property of polymer layer 118 so that it is no longer a photoresist material.

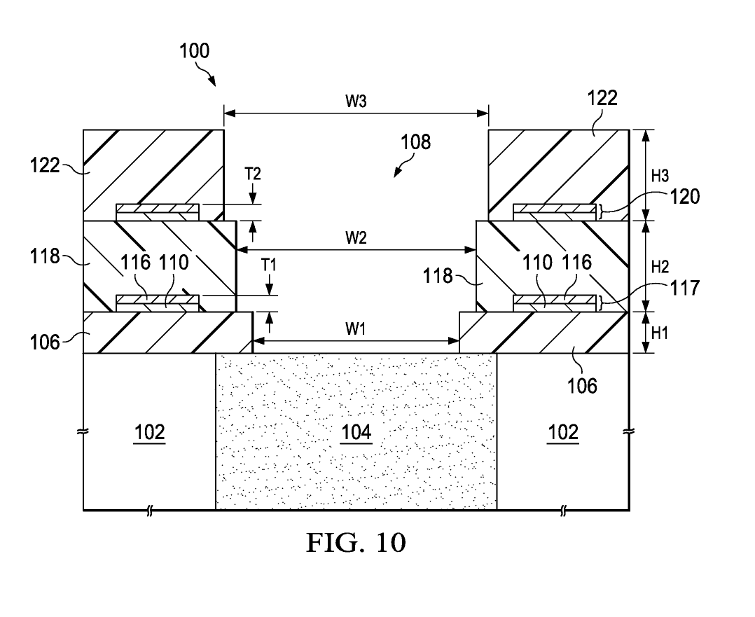

FIG. 10 illustrates the formation of another RDL 120 over polymer layer 118. RDL 120 may be electrically connected to RDL 117, for example, through conductive vias in polymer layer 118 (not shown). RDL 120 may be formed using a substantially similar process as illustrated in FIGS. 3 through 7. RDL 120 may have a thickness T2, which may be larger than thickness T1 of RDL 117. For example, in embodiments where thickness T1 is about 2 μm to about 5 μm, thickness T2 may be about 6 μm to about 8 μm.

FIG. 10 further illustrates the formation and patterning of a third polymer layer 122 over polymer layer 118 and RDL 120. Patterned polymer layer 122 may be substantially similar to polymer layers 118 and 106 both in formation process and make up. Polymer layer 122 is patterned to expose scribe line 108 and to expand scribe line 108 into polymer layer 122. Scribe line 108 in polymer layer 122 may have a width W3, which may be larger than width W2 of scribe line 108 in polymer layer 118. For example, in embodiments where width W2 is about 80 μm to about 90 μm, width W3 may be about 100 μm to about 110 μm. Furthermore, polymer layer 122 may be deposited to have a thickness H3, which may also be relatively similar to thickness H2 of polymer layer 118. For example, in embodiments where thickness H2 is about 6 μm to about 8 μm, thickness H3 also may be about 6 μm to about 8 μm. Alternatively, thickness H3 may be larger than thickness H2.

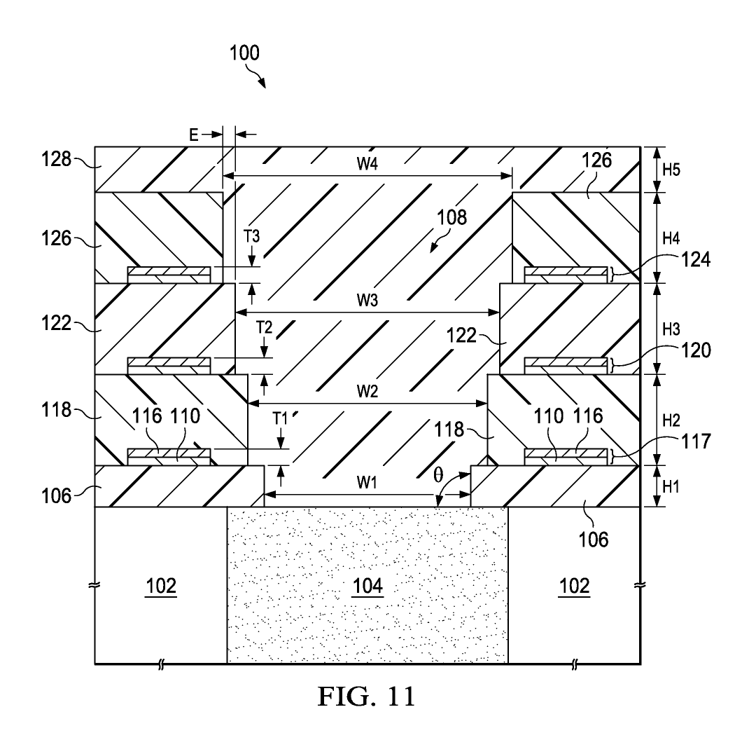

FIG. 11 illustrates the formation of another RDL 124 (e.g., using a similar process as illustrated in FIGS. 3 through 7) and a fourth polymer layer 126 over polymer layer 122. RDL 124 may be electrically connected to RDL 124, for example, through conductive vias in polymer layer 122 (not shown). RDL 124 may have a thickness T3, which may be larger than thickness T1 of RDL 117. For example, in embodiments where thickness T1 is about 2 μm to about 5 μm, thickness T3 may be about 6 μm to about 8 μm. Thickness T3 may or may not be substantially equal to thickness T2 of RDL 120.

Polymer layer 126 is patterned to expose scribe line 108 and to expand scribe line 108 into polymer layer 126. Patterned polymer layer 126 may be substantially similar to polymer layers 122, 118, and 106 in both formation process and make up. Scribe line 108 in polymer layer 126 may have a width W4, which may be larger than width W3 of scribe line 108 in polymer layer 122. For example, in embodiments where width W3 is about 100 μm to about 110 μm, width W3 may be about 120 μm to about 130 μm. Furthermore, polymer layer 126 may be deposited to have a thickness H4, which may also be larger than thickness H3 of polymer layer 122. For example, in embodiments where thickness H3 is about 6 μm to about 8 μm, thickness H4 also may be about 9 μm to about 11 μm.

Thus, scribe line 108 may be formed as an opening extending through multiple polymer layers 106, 118, 122, and 126. The dimensions of scribe line 108 may be wider in each successive polymer layer, and scribe line 108 may have a tiered-step shape illustrated in FIG. 11. Sidewalls of scribe line 108 in each polymer layer may not be vertically aligned. For example, a sidewall of scribe line 108 in two successive polymer layers (e.g., polymer layers 122 and 126) may be separated from by distance E, and distance E may be greater than 0. Furthermore, the thickness of each successive polymer layer may also be progressively larger.

The configured shape (e.g., the step-shape, taper angle θ, and thickness variations) of scribe line 108 allows for improved deposition of subsequent photoresist layers (e.g., under bump metallurgy (UBM) photoresist 128) for forming additional features over polymer layer 126. In some embodiments, UBM photoresist 128 may or may not have a lower elongation and tensile stress as the material of polymer layers 106, 118, 122, and 126. Furthermore, UBM photoresist 128 may have a thickness H5 of at least about 10 μm and minimum resolution of about 200 μm, for example. Due to the shape of scribe line 108, UBM photoresist 128 may be formed more reliability (e.g., having improved thickness control, uniformity, and planarity) over polymer layer 126 even in areas near scribe line 108. Thus, subsequent features may be reliably defined UBM photoresist 128. Furthermore, the scribe line 108 clearly marks an area between dies 102, and the cost of forming scribe line 108 may be comparable to existing scribe lines (e.g., no additional or complex processes are used to pattern scribe line 108).

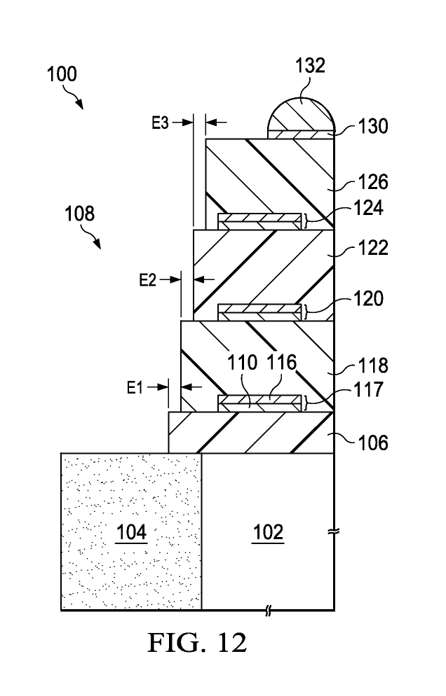

Subsequently, UBM 130 may be formed over polymer layer 126 with increased reliability and UBM photoresist 128 may be removed (e.g., using an ashing process). A connector 132 (e.g., a solder bump) may be disposed over UBM 130. Connector 132 may be used to electrically connect package 100 to other package components such as another device die, interposers, package substrates, printed circuit boards, and the like. UBM 130 and connector 132 may be electrically connected to dies 102 through various interconnect features in polymer layers 106, 118, 122, and 126 (e.g., RDLs and conductive vias). Dies 102 may then be singulated along scribe line 108 using a suitable singulation tool. The resulting package 100 is illustrated in FIG. 12.

As illustrated by FIG. 12, at least some polymer layers 106, 118, 122 and 126 may extend past edges of die 102 in a fan-out layout. Although Due to the shape of scribe line 108, sidewalls of polymer layers 106, 118, 122, and 126 may not be vertically aligned. Sidewalls of polymer layers 106 and 118 are separated by distance E1, sidewalls of polymer layers 118 and 122 are separated by distance E2, and sidewalls of polymer layers 122 and 126 are separated by distance E3. Distances E1, E2, and E3 are each greater than 0, and distances E1, E2, and E3 may or may not be substantially equal. Although a particular configuration of package 100 is illustrated, alternative embodiments may include alternative configurations of package 100 depending on layout design. For example, package 100 may include any number of polymer layers, RDLs, UBMs, and/or connectors depending on layout design. As another example, although polymer layers 106, 118, 122, and 126 are formed over a die in a fan-out package, various polymer layers and scribe lines may be formed over any suitable semiconductor structure.

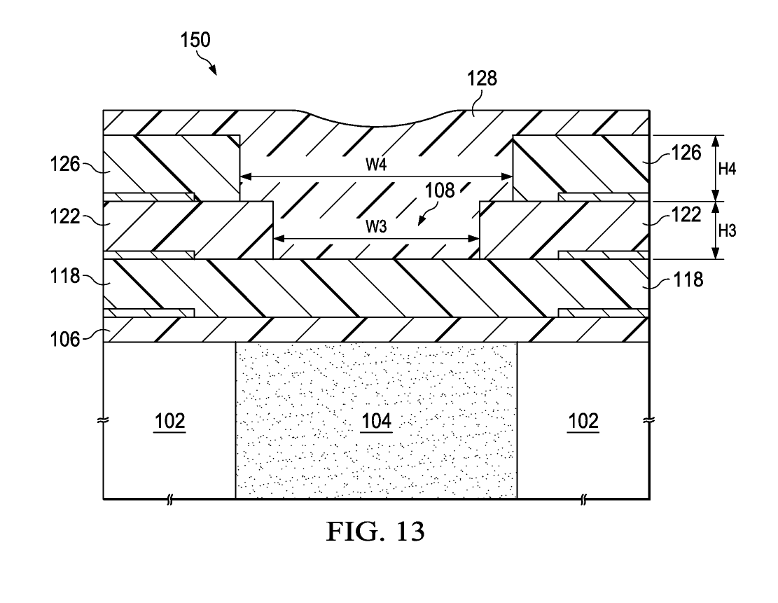

FIG. 13 illustrates a cross-sectional view of a package 150 in accordance with some alternative embodiments. The semiconductor device illustrated in FIG. 13 may be substantially similar to that illustrated in FIG. 11, where like references indicate like elements. However, lower polymer layers 106 and 118 may not be patterned, and scribe line 108 may not extend into polymer layers 106 and 118. Rather, scribe line 108 may be an opening patterned in polymer layers 122 and 126. Scribe line 108 in polymer layer 122 may have a width W3, and scribe line 108 in polymer layer 126 may have a width W4. Width W4 may be greater than width W3 in various embodiments. Furthermore, thickness H3 of polymer layer 122 may be greater than thickness H4 of polymer layer 126. Thus, scribe line 108 may still have a multi-tiered step shape. As illustrated by FIG. 13, a well-defined scribe line 108 may be formed without necessarily patterning each polymer layer. Thus, in alternative embodiments, scribe line 108 may or may not extend through all polymer layers in a device die. Furthermore, after singulation of the package 200 (not shown), sidewalls of polymer layers 106 and 118 may be vertically aligned while sidewalls of polymer layers 122 and 126 may not be vertically aligned.

FIGS. 14 through 20 illustrate intermediary stages of manufacturing an example device package 250 in accordance with various embodiments. Package 250 may include similar features as package 100 where like reference numerals indicate like elements. The features of package 250 are illustrated in greater detail than package 100. In alternative embodiments, a device package may include any combination of the features shown, a subset of the illustrated features, or additional features, and the illustrated configuration of package 250 is non-limiting.

Referring to FIG. 14, package 250 includes device dies 102 illustrated in greater detail than FIG. 1. Each device die 102 includes a substrate 200. Substrate 200 may be a bulk silicon substrate although other semiconductor materials including group III, group IV, and group V elements may also be used. Active devices (now shown) such as transistors may be formed on the top surface of substrate 200. An interconnect structure 202 may be formed over the active devices and substrate 200.

Interconnect structure 202 may include inter-layer dielectric (ILD) and/or inter-metal dielectric layers (IMDs) containing conductive features (e.g., conductive lines and vias comprising copper, aluminum, tungsten, combinations thereof, and the like) formed using any suitable method. The ILD and IMDs may be formed of low-k dielectric materials having k values, for example, lower than about 4.0 or even 2.8. In some embodiments, the ILD and IMDs may be made of, for example, silicon oxide, SiCOH, and the like. Interconnect structure 202 electrically connect various active devices to form functional circuits within dies 102.

Additional input/output (I/O) and passivation features may be formed over interconnect structure 202. For example, contact pads 204 may be formed over the interconnect structure 202 and may be electrically coupled to the active devices through various conductive lines and vias in interconnect structure 202. Passivation layer 206 may be formed over interconnect structure 202 and contact pads 204. In some embodiments, passivation layer 206 may comprise non-organic materials such as silicon oxide, un-doped silicate glass, silicon oxynitride, and the like. Although not illustrated, portions of passivation layer 206 may also cover edge portions of contact pads 204. The various features of dies 102 may be formed by any suitable method and are not described in further detail herein. Furthermore, the general features of dies 102 described above are but one example embodiment, and dies 102 may include any combination of the above features as well as other features.

Polymer layers 208 having conductive pillars 210 may be formed over each die 102. Conductive pillars 210 may extend through polymer layer 208 and electrically connect to contact pads 204. Polymer layer 208 and conductive pillars 210 may provide an interface and structure support for the formation of fan-out RDL and polymer layers over dies 102. Molding compound 104 may be dispensed around dies 102 and polymer layer 208. In a top down view of package 200 (not shown), molding compound 104 may encircle dies 102 and polymer layer 208.

Polymer layer 106 may be formed over polymer layer 208 and molding compound 104. Additionally, RDLs 117 may be formed over polymer layer 106. Conductive vias in polymer layer 106 may electrically connect RDLs 117 to conductive pillars 210, which may further electrically connect RDLs 117 to dies 102. In various embodiments, polymer layer 106 may have a lateral dimension L1 over each die 102, and polymer layer 106 may extend past edges of respective dies 102 to form a fan-out layer. Furthermore, a portion of polymer layer 106 corresponding to an area between dies 102 may be patterned to include a scribe line 108.

Package 250 may include further interconnect features. For example, dies 102 may be attached to backside polymer layer 214 (e.g., having backside RDLs 215) by adhesive layers 212. Through molding vias (TMVs) 212 may extend through molding compound 104 and electrically connect backside RDLs 215 to RDLs 117. The inclusion of backside RDLs 115 in backside polymer layer 214 may allow for increased flexibility for electrical routing and interconnection in package 200. A carrier 216 (e.g., a glass or ceramic carrier) may be disposed under backside polymer layer 214. Carrier 216 may provide support during the formation various features in package 250.

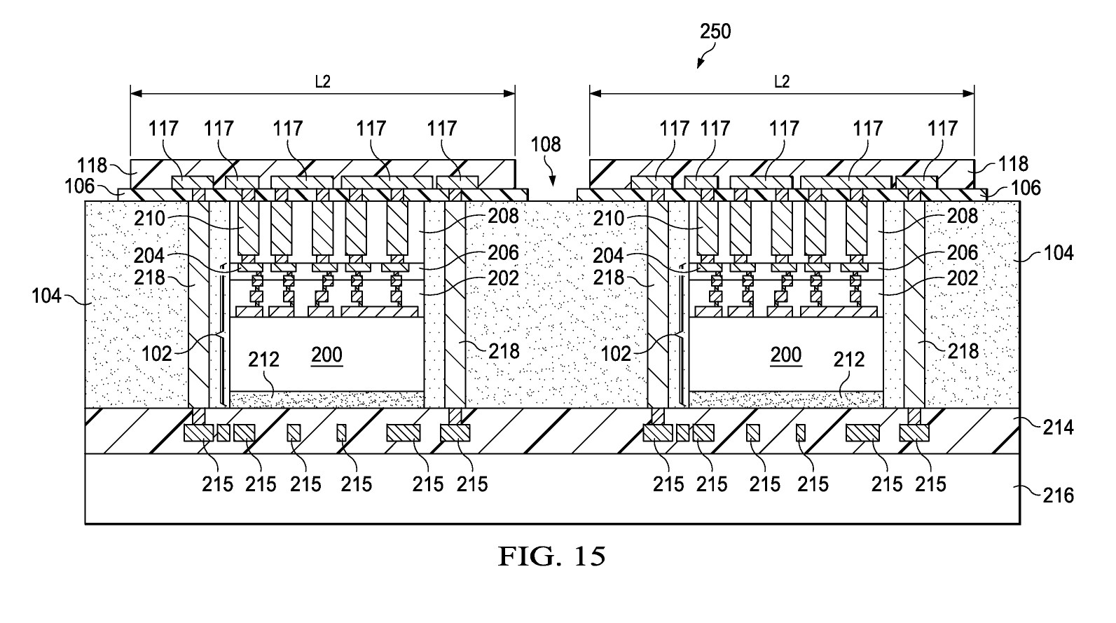

Referring next to FIG. 15, polymer layer 118 may be formed over polymer layer 106 and RDLs 117. Polymer layer 118 may extend past edges of dies 102, and polymer layer 118 may also be a fan-out layer. A patterning may be performed to extend scribe line 108 into polymer layer 118. In various embodiments, sidewalls of polymer layers 106 and 118 in scribe line 108 may not be vertically aligned. Polymer layer 118 has a lateral dimension L2, which may be smaller than lateral dimension L1 of polymer layer 106. Furthermore, polymer layer 118 may be thicker than polymer layer 106.

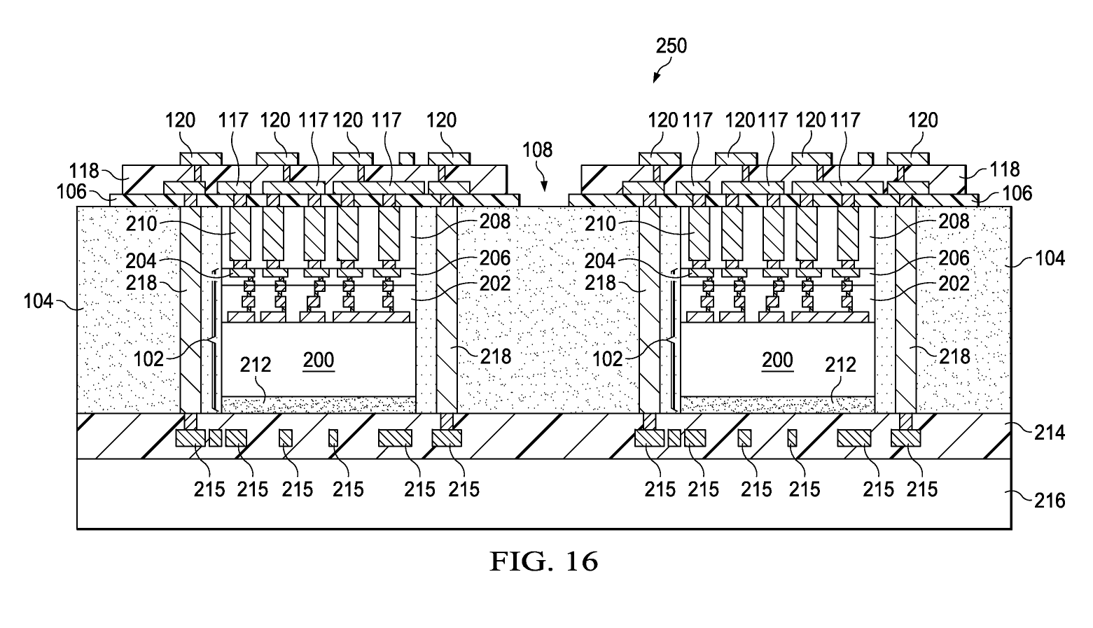

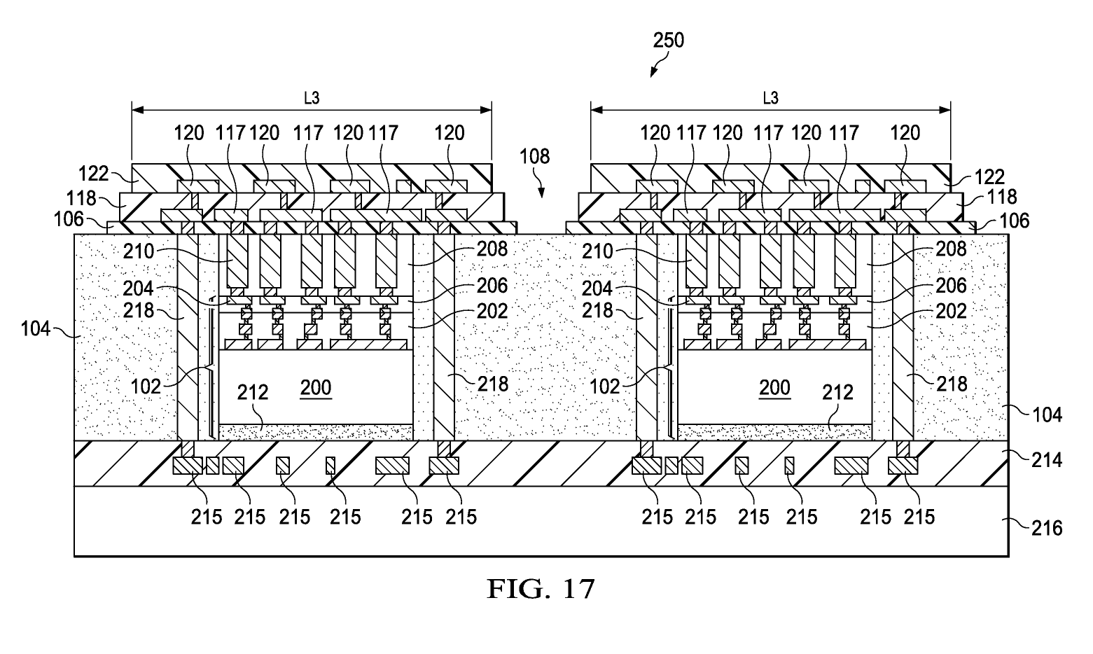

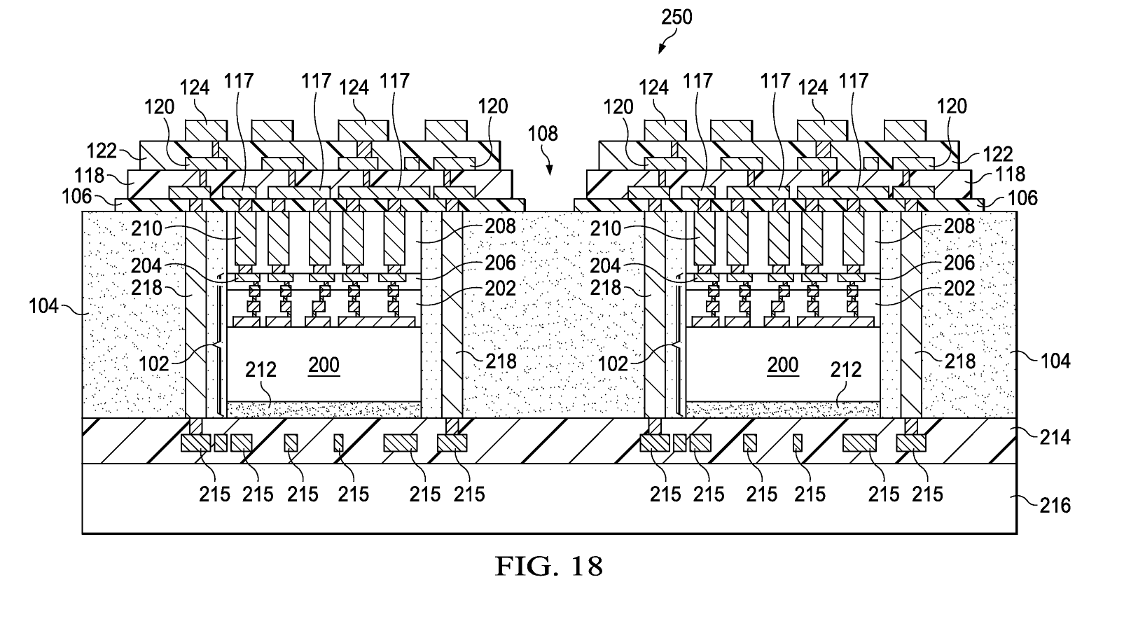

FIG. 16 illustrates the formation of RDLs 120 over polymer layer 118. Conductive vias in polymer layer 118 electrically connect RDLs 120 to RDLs 117. In some embodiments, RDLs 120 may be thicker than RDLs 117. Next, in FIG. 17, polymer layer 122 may be formed over polymer layer 118 and RDLs 120. Polymer layer 122 may extend past edges of dies 102, and polymer layer 122 may also be a fan-out layer. A patterning may be performed to extend scribe line 108 into polymer layer 122. In various embodiments, sidewalls of polymer layers 106, 118, and 122 in scribe line 108 may not be vertically aligned. Polymer layer 122 has a lateral dimension L3, which may be smaller than lateral dimension L2 of polymer layer 118, which is smaller than lateral dimension L1 of polymer layer 106. In some embodiments, polymer layer 122 may have substantially a same thickness or may be thicker than polymer layer 118.

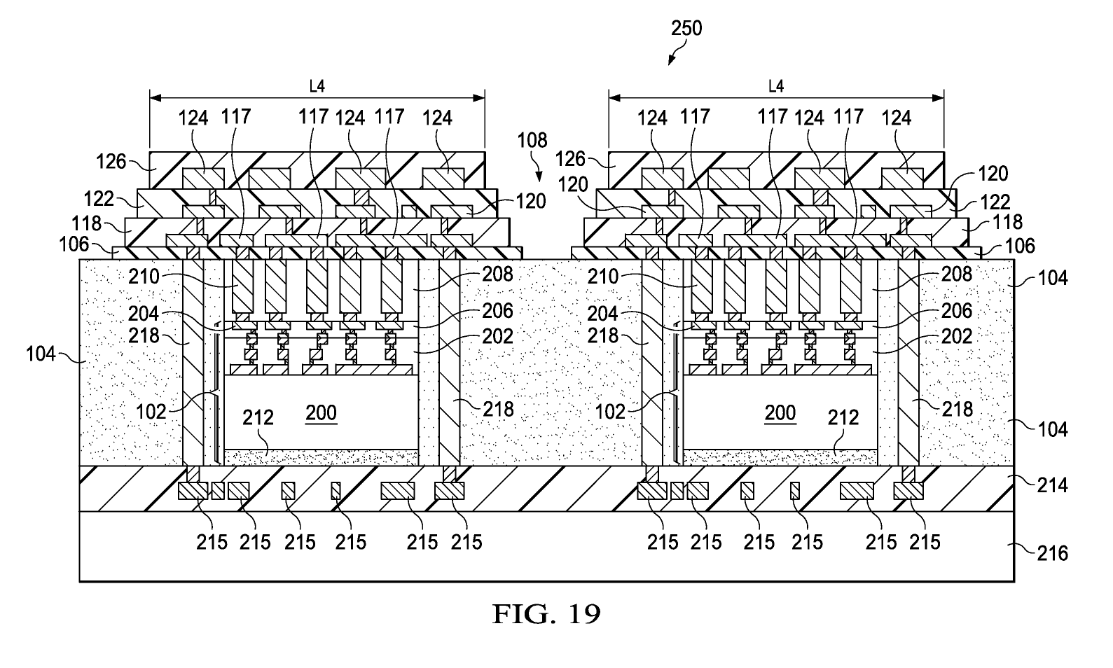

FIG. 18 illustrates the formation of RDLs 124 over polymer layer 122. Conductive vias in polymer layer 122 electrically connect RDLs 124 to RDLs 120. In some embodiments, RDLs 124 may be thicker than RDLs 120. Next, in FIG. 19, polymer layer 126 may be formed over polymer layer 122 and RDLs 124. Polymer layer 126 may extend past edges of dies 102, and polymer layer 126 may also be a fan-out layer. A patterning may be performed to extend scribe line 108 into polymer layer 126. In various embodiments, sidewalls of polymer layers 106, 118, 122, and 126 in scribe line 108 may not be vertically aligned. Polymer layer 126 has a lateral dimension L4, which may be smaller than lateral dimension L3 of polymer layer 122. In some embodiments, polymer layer 126 may be thicker than polymer layer 122.

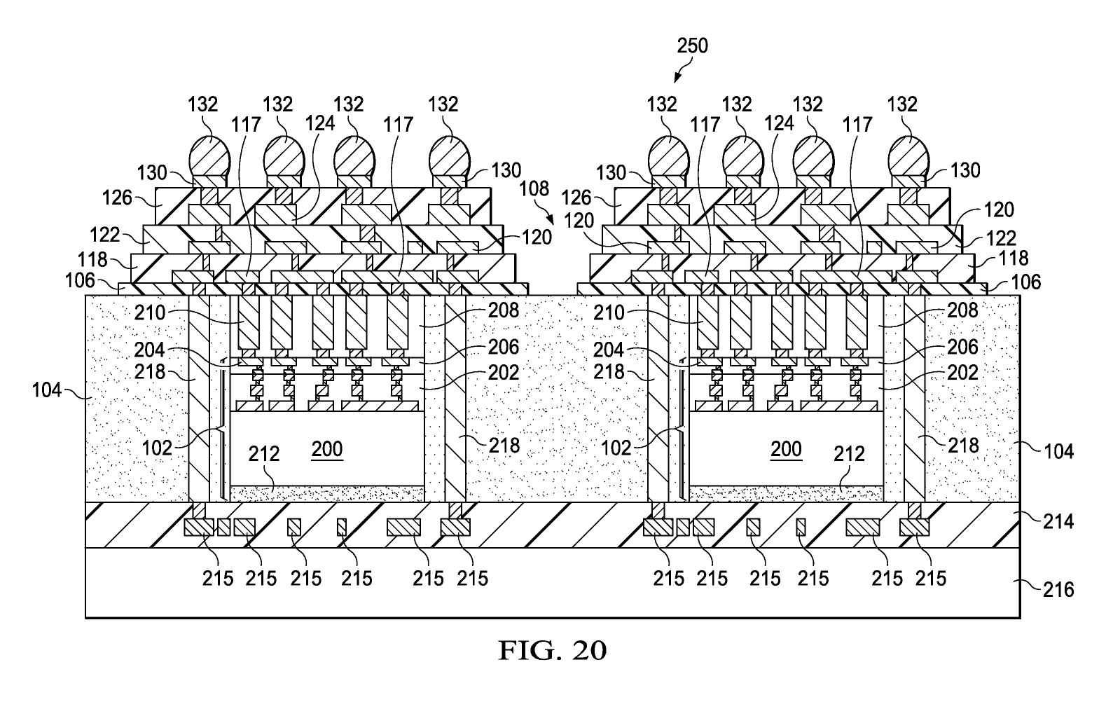

Subsequently, as illustrated by FIG. 20, UBMs 130 may be formed over polymer layer 126. UBMs 130 may be electrically connected to RDLs 124 in polymer layer 126. The configuration of polymer layers 106, 118, 122, and 126 as well as scribe line 108 help increase reliability during the formation of UBMs 130, including UBMs 130 disposed adjacent scribe line 108. For example, the vertical misalignment of sidewalls of polymer layers 106, 118, 122, and 126 in scribe line 108 improves the uniformity of photoresists (e.g., for defining UBMs 130) disposed over polymer layer 126 and in scribe line 108.

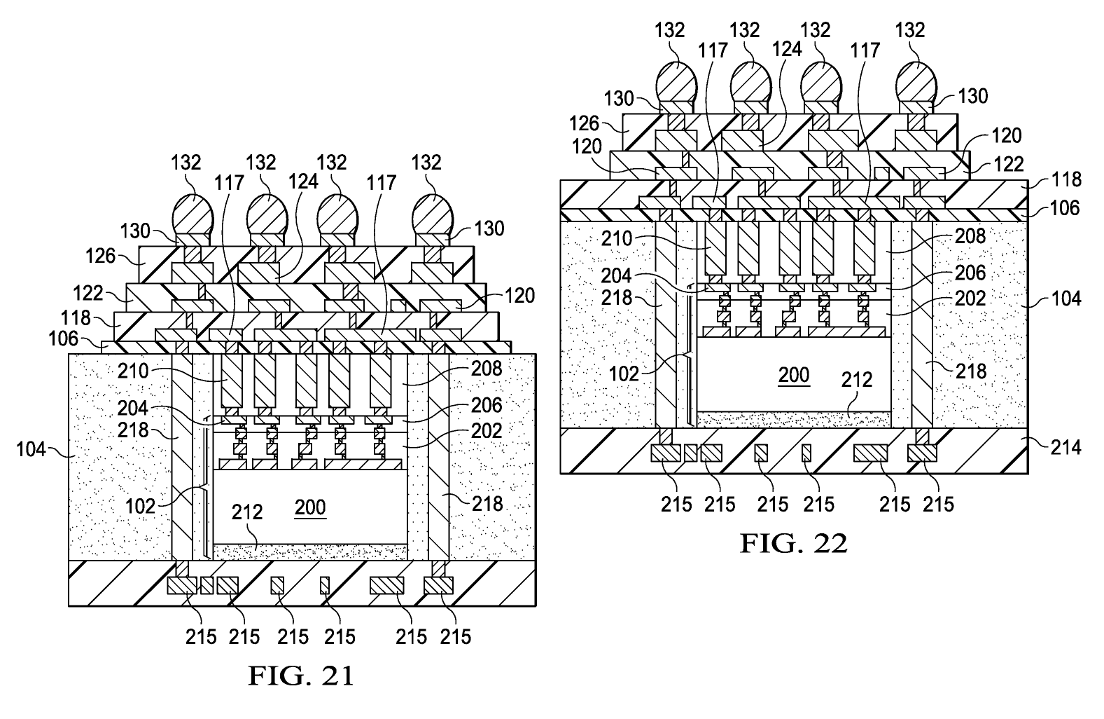

Connectors 132 (e.g., a solder bump) may be disposed over UBMs 130. Connectors 132 may be used to electrically connect package 250 to other package components such as another device die, interposers, package substrates, printed circuit boards, and the like. Carrier 216 may then be removed, and dies 102 may then be singulated along scribe line 108 using a suitable singulation tool. For example, a die saw may be performed to separate dies 102 along scribe line 108. The resulting device package is illustrated in FIG. 21.

FIG. 22 illustrates a cross-sectional view of a package device in accordance with alternative embodiments. For example, FIG. 22 may illustrate an embodiment similar to the embodiment illustrated in FIG. 13 after die singulation. As illustrated by FIG. 22, polymer layers 106 and 118 may have substantially similar lateral dimensions. Sidewalls of polymer layers 106 and 118 may be vertically aligned with each other as well as with sidewalls of molding compound 104. Polymer layer 122 may have sidewalls that are vertically misaligned with polymer layer 126, and both polymer layers 122 and 126 may have sidewalls that are not vertically aligned with sidewalls of polymer layers 106 and 118. Furthermore, polymer layer 126 may have a lateral dimension that is smaller than a lateral dimension of polymer layer 122.

In accordance with an embodiment, a device includes a die, a molding compound extending along sidewalls of the die, and a first polymer layer over the die and the molding compound. The first polymer layer has a first lateral dimension. The device further includes a second polymer layer over the first polymer layer. The second polymer layer has a second lateral dimension, where the second lateral dimension is less than the first lateral dimension.

In accordance with another embodiment a device includes a die, a first polymer layer over the die, and a first redistribution line (RDL) over the first polymer layer. The device further includes a second polymer layer over the first RDL and the first polymer layer. Sidewalls of the first and the second polymer layers are not vertically aligned.

In accordance with yet another embodiment, a method includes patterning a first portion of a scribe line in a first polymer layer and forming a redistribution line (RDL) over the first polymer layer. A second polymer layer is formed over the RDL and the first polymer layer. The method further includes patterning a second portion of the scribe line in the second polymer layer. The first and the second portions are connected, and the second portion of the scribe line is wider than the first portion of the scribe line

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1.-14. (canceled)

15. A method comprising:
patterning a first portion of a scribe line in a first polymer layer;
forming a redistribution line (RDL) over the first polymer layer;
forming a second polymer layer over the RDL and the first polymer layer; and
patterning a second portion of the scribe line in the second polymer layer, wherein the first and the second portions are connected, and wherein the second portion of the scribe line is wider than the first portion of the scribe line.

16. The method of claim 15, wherein patterning the first portion of the scribe line in the first polymer layer comprises a photolithography process.

17. The method of claim 16, wherein after the photolithography process, performing a curing process on the first polymer layer, wherein after the curing process, the first polymer layer is not a photoresist.

18. The method of claim 15, wherein forming the second polymer layer comprises blanket depositing the second polymer layer, and wherein patterning the second portion of the scribe line in the second polymer layer comprises removing portions of the second polymer layer in the first portion of the scribe line.

19. The method of claim 15, wherein forming the second polymer layer comprises forming the second polymer layer thicker than the first polymer layer.

20. The method of claim 15, further comprising forming the first polymer layer over a third polymer layer, wherein the scribe line does not extend into the third polymer layer.

21. A method comprising:
forming a first polymer layer over a first die and a second die;
patterning first opening extending through the first polymer layer, wherein the first opening is aligned with an area between the first die and the second die;
forming a second polymer layer over the first polymer layer, wherein the second polymer layer is thicker than the first polymer layer; and
patterning a second opening extending through the second polymer layer, wherein the second opening is connected to the first opening.

22. The method of claim 21, wherein the second opening is wider than the first opening, and wherein the second opening exposes a top surface of the first polymer layer.

23. The method of claim 21 further comprising:
forming a third polymer layer over the second polymer layer, wherein the third polymer layer is thicker than the second polymer layer; and
patterning a third opening in the third polymer layer connected to the second opening.

24. The method of claim 23, wherein the third opening is wider than the second opening, and wherein the third opening exposes a top surface of the second polymer layer.

25. The method of claim 21, wherein forming the first polymer layer comprises forming the first polymer layer over a fourth polymer layer disposed over the first die and the second die, and wherein patterning the first opening comprises exposing a continuous portion of the fourth polymer layer extending from a first sidewalls of the first opening to a second sidewall of the first opening.

26. The method of claim 21 further comprising:
forming a photoresist over the second polymer layer and extending into the first opening and the second opening; and
using the photoresist to define an under bump metallurgy (UBM) over the second polymer layer.

27. The method of claim 21 further comprising separating the first die from the second die along a scribe line defined by the first opening and the second opening.

28. A method comprising:
providing a first die, a second die, and a molding compound disposed between the first die and the second die;
forming a first polymer layer over the first die and the second die;
patterning a first opening in the first polymer layer using a photolithography process, wherein the first opening is disposed directly over the molding compound;
after patterning the first opening, curing the first polymer layer;
forming a second polymer layer over the first polymer layer;
patterning a second opening in the second polymer layer, wherein the second opening is connected to the first opening, and wherein sidewalls of the second opening are spaced apart from sidewalls of the first opening; and
separating the first die from the second die along a scribe line defined by the first opening and the second opening.

29. The method of claim 28, forming the first polymer layer comprises forming a photosensitive layer, and wherein after curing the first polymer layer, the first polymer layer is no longer photosensitive.

30. The method of claim 28, wherein curing the first polymer layer comprises heating the first polymer layer.

31. The method of claim 28, wherein forming the second polymer layer comprises forming the second polymer layer thicker than the first polymer layer.

32. The method of claim 28, wherein forming the first polymer layer comprises forming the first polymer layer over a third polymer layer disposed over the molding compound, wherein the scribe line does not extend through the third polymer layer.

33. The method of claim 28 further comprising forming a redistribution line between the first polymer layer and the second polymer layer.

34. The method of claim 28 wherein forming the second polymer layer comprises forming a portion of the second polymer layer in the first opening, and wherein patterning the second opening comprises removing the portion of the second polymer layer in the first opening.
